(19) United States
(12) Patent Application Publication
(10) Pub. No.: US 2006/0110923 A1
(43) Pub. Date: May 25, 2006

(54) Barrier polishing solution

(76) Inventors: Zhendong Liu, Newark, DE (US); John Quanci, Haddonfield, NJ (US); Robert E. Schmidt, Bear, DE (US)

Correspondence Address: Rohm and Haas Electronic;Materials CMP Holdings, Inc., Suite 1300, 1105 North Market Street, Wilmington, DE, 19899, US

(21) Appl. No.: 10/996,684

(22) Filed: Nov. 24, 2004

(51) Int. Cl. C09K 13/00; H01L 21/302; B44C 1/22

(52) U.S. Cl. 438/692; 216/88; 252/79.1; 252/79.2

(57) ABSTRACT

The polishing solution is useful for preferentially removing barrier materials in the presence of nonferrous interconnect metals with limited erosion of dielectrics. The polishing solution comprises 0 to 20 weight percent oxidizer, inhibitor for reducing removal rate of the nonferrous interconnect metals, ammonium salt, 0.1 to 50 weight percent silica containing 0.001 to 1 ppm sodium and 0.001 to 1 ppm potassium, and balance water; and the solution having a pH of less than 3 with an inorganic acid used as a titrant.

### BACKGROUND OF THE INVENTION

The invention relates to chemical mechanical polishing (CMP) formulations for removing barrier metals and, more particularly, to polishing compositions for selectively removing barrier metals in the presence of interconnect structures in integrated circuit devices.

In recent years, the semiconductor industry has increasingly relied upon copper electrical interconnects in forming integrated circuits. These copper interconnects have a low electrical resistivity and a high resistance to electromigration. Since copper is very soluble in many dielectric materials, such as silicon dioxide and low-k or doped versions of silicon dioxide, a diffusion barrier layer is necessary to prevent the diffusion of copper into the underlying dielectric material. Typical barrier materials include, tantalum, tantalum nitride, tantalum-silicon nitrides, titanium, titanium nitrides, titanium-silicon nitrides, titanium-titanium nitrides, titanium-tungsten, tungsten, tungsten nitrides and tungsten-silicon nitrides.

In response to increasing demands for high density integrated circuits, semiconductor producers now fabricate integrated circuits containing multiple overlying layers of metal interconnect structures. During device fabrication, planarizing each interconnect layer improves packing density, process uniformity, product quality and most importantly, enables manufacturing of multiple layer integrated circuits. Semiconductor producers rely upon CMP as a cost effective means of producing flat substrate surfaces. The CMP process is typically carried out in a two-step sequence. First, the polishing process uses a “first-step” slurry specifically designed to rapidly remove copper. For example, Carpio et al., in “Initial Study on Copper CMP Slurry Chemistries” Thin Solid Films, 262 (1995), disclose the use on a 5 weight percent nitric acid solution for efficient copper removal. Similarly, Kondo et al., in U.S. Pat. No. 6,117,775, disclose the use of nitric acid and BTA for copper removal.

After the initial copper removal, a “second-step” slurry removes the barrier material. Typically, second-step slurries require excellent selectivity to remove the barrier material without adversely impacting the physical structure or electrical properties of the interconnect structure.

Because it was traditionally perceived that alkaline polishing slurries have a much higher tantalum and tantalum nitride removal rate than acidic slurries, commercial second-step slurries typically have a neutral-to-basic pH. Another factor pointing to the advantages of neutral to basic pH barrier metal polishing slurries relates to the need to preserve the metal overlying the barrier metal during the second-step polishing. The metal removal rate should be very low to reduce dishing of the metal interconnects.

In acidic slurries that include oxidizing agents, copper tends to have both a high removal rate and a high static etch rate. Cote et al. however, in U.S. Pat. No. 6,375,693, disclose an acidic CMP slurry for barrier materials. The slurry of Cote et al. operates with a hydrogen peroxide oxidizer, a benzotriazole inhibitor and a sulfated fatty acid at a pH range of 2 to 7.5. Similarly, Wojtczak et al., in U.S. Pat. No. 6,409,781, disclose an acidic polishing slurry that relies upon a potassium iodate oxidizer, iminodiacetic acid as the copper corrosion inhibitor and nitric acid as the copper activator to selectively polish the barrier material.

Future low-k and ultra-low-k integrations of the IC structure will require low metal and dielectric losses in the CMP step. Accordingly, a selective slurry for barrier removal will most probably be adopted. While neutral-to-basic polishing slurries have advantages known to those skilled in the art, such as those described above, these slurries also tend to have low tantalum removal rates. In addition, because tantalum is readily oxidized, the oxidizing agents in the slurry can react with the tantalum to form an oxide layer on the surface. In view of the above, there exists a need to provide a second-step slurry that possesses a high removal rate of barrier materials, excellent selectivity to interconnect metals and controlled removal of dielectric materials. In addition, there is a need for a slurry that has ultra-low trace metals so that there is no metal diffusion into the dielectric layer. This is especially important for low-k dielectric materials such as carbon-doped oxide (CDO). Once the CDO is contaminated with metal ions such as K+ and Na+, it is very difficult to remove the contaminated layer. Contamination is avoided by using a high-purity silica and using nitric acid as the titrant for the slurry.

### STATEMENT OF THE INVENTION

The invention provides a polishing solution useful for preferentially removing barrier materials in the presence of nonferrous interconnect metals with limited erosion of dielectrics comprising: 0 to 20 weight percent oxidizer, inhibitor for reducing removal rate of the nonferrous interconnect metals, ammonium salt, 0.1 to 50 weight percent silica containing 0.001 to 1 ppm sodium and 0.001 to 1 ppm potassium and balance water; and the solution having a pH of less than 3 with an inorganic acid used as the titrant.

In another aspect, the invention provides a polishing solution useful for preferentially removing barrier materials in the presence of nonferrous interconnect metals with limited erosion of dielectrics comprising 0.01 to 15 weight percent oxidizer, 0.001 to 10 weight percent inhibitor for reducing removal rate of the nonferrous interconnect metals, 0.001 to 3 weight percent ammonium salt, 0.1 to 50 weight percent silica containing 0.001 to 0.5 ppm sodium and 0.001 to 0.5 ppm potassium and balance water the solution having a pH of less than or equal to 5 with an inorganic acid used as the titrant.

In another aspect, the invention provides a method of polishing semiconductor substrates, including the steps of: polishing the semiconductor substrate with a polishing solution and a polishing pad, the polishing solution useful for preferentially removing barrier materials in the presence of nonferrous interconnect metals with limited erosion of dielectrics comprising: 0 to 20 weight percent oxidizer, inhibitor for reducing removal rate of the nonferrous interconnect metals, ammonium salt, 0.1 to 50 weight percent silica containing 0.001 to 1 ppm sodium and 0.001 to 1 ppm potassium and balance water; and the solution having a pH of less than 3 with an inorganic acid used as the titrant.

### DETAILED DESCRIPTION

It has been discovered that use of aqueous silica-containing solutions having 0.001 to 1 ppm sodium and 0.001 to 1 ppm potassium with the use of an inorganic acid to bring the pH to less than 5 will provide a contaminant free dielectric layer not obtainable with conventional slurries. The polishing solution should be free of organic acids but can also optionally include pH buffers, oxidizer, inhibitor for reducing removal rate of the nonferrous interconnect metals, and ammonium salt.

For purposes of this specification, dielectric includes silica-base materials such as TEOS, low-k and ultra-low-k materials (some ultra-low-k materials are not silica-base). To polish low-k and ultra-low-k dielectric materials, it is important to maintain low pressure to decrease the delamination and fracture of these materials. However, low pressure yields low barrier material (Ta/TaN) removal rate, which is undesirable for wafer throughput. Fortunately, acidic polishing solutions having a strong oxidizer have demonstrated high barrier removal rates in comparison to conventional alkaline barrier slurries that operate at low pressures. The barrier material may include the following: tantalum, tantalum nitride, tantalum-silicon nitrides, titanium, titanium nitrides, titanium-silicon nitrides, titanium-titanium nitrides, titanium-tungsten, tungsten, tungsten nitrides and tungsten-silicon nitrides.

The polishing slurry contains a limited amount of metallic ions, such as sodium and potassium (0.001 to 1 ppm Na and 0.001 to 1 ppm K) to limit contamination of a dielectric, such as low-k or an ultra-low-k dielectric. Preferably, the solution contains 0.001 to 0.5 ppm sodium and 0.001 to 0.5 ppm potassium. Most preferably, the solution contains 0.001 to 0.1 ppm sodium and 0.001 to 0.1 ppm potassium and less than 0.2 ppm total alkali metals of lithium, sodium, potassium, rubidium, cesium and francium. As counter ions, a small amount of alkali metals can be useful for improved dissolving of some organics, such as ethylenediaminetetraacetic acid (EDTA).

The barrier metal polishing composition optionally includes an abrasive for “mechanical” removal of the barrier material. The CMP composition includes an abrasive for “mechanical” removal of barrier layers. The abrasive is preferably a colloidal abrasive. Example abrasives include the following: inorganic oxide, metal boride, metal carbide, metal hydroxide, metal nitride, or a combination comprising at least one of the foregoing abrasives. Suitable inorganic oxides include, for example, silica (SiO₂), alumina (Al₂O₃), zirconia (ZrO₂), ceria (CeO₂), manganese oxide (MnO₂), and mixtures thereof. Alumina is available in many forms such as alpha-alumina, gamma-alumina, delta-alumina, and amorphous (non-crystalline) alumina. Other suitable examples of alumina are boehmite (AlO(OH)) particles and mixtures thereof. Modified forms of these inorganic oxides such as polymer-coated inorganic oxide particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, and mixtures comprising at least one of the foregoing metal carbides, boride and nitrides. Diamond may also be utilized as an abrasive if desired. Alternative abrasives also include polymeric particles and coated polymeric particles. The preferred abrasive is silica containing 0.001 to 1 ppm sodium and 0.001 to 1 ppm potassium.

The abrasive has a concentration in the aqueous phase of the polishing composition of 0.1 to 50 weight percent—this specification refers to all concentrations in weight percent, unless specifically expressed otherwise. Preferably, the abrasive concentration is 0.1 to 40 weight percent. And most preferably, the abrasive concentration is 0.25 to 35 weight percent. Typically, increasing abrasive concentration increases the removal rate of dielectric materials; and it especially increases the removal rate of low-k dielectric materials, such as carbon-doped oxide. For example, if a semiconductor manufacturer desires an increased low-k dielectric removal rate, then increasing the abrasive content can increase the dielectric removal rate to the desired level.

The abrasive preferably has an average particle size of less than 250 nm for preventing excessive metal dishing and dielectric erosion. For purposes of this specification, particle size refers to the colloidal silica's average particle size. Most preferably, the silica has an average particle size of less than 100 nm to further reduce metal dishing and dielectric erosion. In particular, an average abrasive particle size less than 15 nm removes the barrier metal an acceptable rate without excessive removal of the dielectric material. For example, the least dielectric erosion and metal dishing occur with a colloidal silica having an average particle size is 2 to 15 nm. Decreasing the size of the colloidal silica tends to improve the selectivity of the solution; but it also tends to decrease the barrier removal rate. In addition, the preferred colloidal silica may include additives, such as dispersants to improve the stability of the silica at acidic pH ranges. One such abrasive is colloidal silica containing less than 0.30 ppm Na and 0.20 ppm K that is available from Fuso Chemical Company, Osaka, Japan.

In addition, high-purity silica particles can also serve to decrease the yellowing rate of the polishing solutions. For example maintaining total transition metal concentration to less than 1 part per million (ppm) further increases the solution's ability to decrease yellowing. Furthermore, limiting potassium and sodium to less than 1 ppm reduces adverse diffusion of these detrimental components into dielectric layers. In addition, adding up to 1 weight percent complexing agent, such as EDTA, can further stabilize the slurry and prevent yellowing.

Optionally, the removal rate of barrier layers, such as tantalum, tantalum nitride, titanium and titanium nitride is preferably adjusted by the use of an oxidizing agent. Suitable oxidizers include, for example, hydrogen peroxide, monopersulfates, iodates, magnesium perphthalate, peracetic acid and other peracids, persulfates, bromates, periodates, nitrates, iron salts, cerium salts, manganese (Mn) (III), Mn (IV) and Mn (VI) salts, silver salts, copper salts, chromium salts, cobalt salts, halogens, hypochlorites, or combinations comprising at least one of the foregoing oxidizers. The preferred oxidizer is hydrogen peroxide. It is to be noted that the oxidizer is typically added to the polishing composition just prior to use and in these instances the oxidizer is contained in a separate package.

It is desirable to use an amount of 0 to 20 weight percent oxidizer. Preferably, the oxidizer is 0.001 to 15 weight percent. Most preferably, the composition contains 0.05 to 10 weight percent oxidizer. Adjusting the amount of oxidizer, such as peroxide can also control the metal interconnect removal rate. For example, increasing the peroxide concentration increases the copper removal rate. Excessive increases in oxidizer, however, provide an adverse impact upon polishing rate.

Additionally, the solution may contain inhibitor to control nonferrous interconnect removal rate by static etch or other removal mechanism. Adjusting the concentration of an inhibitor adjusts the nonferrous interconnect metal removal rate by protecting the metal from static etch. Preferably, the solution contains 0.001 to 10 weight percent inhibitor for inhibiting static etch of nonferrous metal, for example, copper interconnects. Most preferably, the solution contains 0.05 to 2 weight percent inhibitor. The inhibitor may consist of a mixture of inhibitors. Azole inhibitors are particularly effective for copper and silver interconnects. Typical azole inhibitors include benzotriazole (BTA), mercaptobenzothiazole (MBT), tolytriazole and imidazole. BTA is a particularly effective inhibitor for copper and silver interconnects.

The polishing composition has a pH of less than 7 and a balance water. Preferably, the pH is less than or equal to 5. Preferably, the polishing composition includes an inorganic pH adjusting agent to reduce the pH of the polishing composition to an acidic pH less than 7 with a balance water. Preferably, the pH adjusting agent only contains an impurity level concentration of metallic ions. In addition, the solution most preferably relies upon a balance of deionized water to limit incidental impurities. Preferably adjusting agent is an inorganic acid, such as nitric acid, sulfuric acid, hydrochloric acid, hydrofluoric acid and phosphoric acid. The most advantageous pH adjusting agent is nitric acid (HNO₃). Typically, the solution has a pH of 1.5 to 5. Most preferably, the pH is 2 to 4.

At a pH level below 5, the polishing composition can provide a high barrier metal removal rate, even with a relatively low abrasive concentration. This low abrasive concentration can improve the polishing performance of a CMP process by reducing undesired abrasive induced defects, such as scratching. In addition, at a pH below 4, the polishing composition can be formulated with abrasive particles having a relatively small particle size. For example, a particle size of as small as approximately 10 nm still provides an acceptable Ta/TaN removal rate. By employing an abrasive having a relatively small particle size and formulating the acidic polishing composition at a low abrasive concentration, polishing defects are reduced to excellent levels.

It has been found that the optional addition of ammonium salts facilitates controlled removal rate of silicon oxide-containing layers, such as TEOS layers at acidic pH levels; and thus they permit controlling the silicon oxide-containing material's removal rate. The ammonium salts are organic ammonium salts formed with compounds to include the structure: 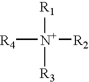
R₁, R₂, R₃ and R₄ are radicals that can be the same or different. The composition operates at acidic pH levels where the ammonium compound becomes ionized. Example anions include, nitrate, sulfate, halides (such as, bromide, chloride, fluoride and iodide), citrate, phosphate, oxalate, malate, gluconate, hydroxide, acetate, borate, lactate, thiocyanate, cyanate, sulfonate, silicate, per-halides (such as, perbromate, perchlorate and periodate), chromate, and mixtures thereof. It is possible to add the salt directly to the composition or to form the salt in situ. For example, adding tetrabutylammonium hydroxide (TBAH) to a nitric acid solution at a pH of 2.5 forms the tetrabutylammonium nitrate.

A preferable ammonium salt combination is that formed from reacting tetrabutylammonium hydroxide with hydrofluoric acid. This combination reacts at low pH levels to form a tetrabutylammonium fluoride salt. Although the exact mechanism is unclear (the fluoride salt dissociates to provide fluoride ions in solution), having organic ammonium fluoride salts in solution further accelerates the TEOS removal rate.

R₁ is an organic that has a carbon chain length of 2 to 15 carbon atoms. More preferably, R₁ has a carbon chain length of 2 to 10. Most preferably, R₁ has a carbon chain length of 2 to 5 carbon atoms. The organic of R₁ may be a substituted or unsubstituted aryl, alkyl, aralkyl, or alkaryl group.

Preferably, R₂, R₃ and R₄ are organic compounds, such as, a substituted or unsubstituted aryl, alkyl, aralkyl, or alkaryl group; or hydrogen. If R₂, R₃ or R₄ is an organic compound, then the organic compound preferably has a carbon chain length of 2 to 15 carbon atoms; more preferably, it has a carbon chain length of 2 to 10 carbon atoms; and most preferably it has a carbon chain length of 2 to 5 carbon atoms.

Suitable compounds for forming ammonium salts include tetraethyl ammonium, tetrabutylammonium, benzyltributylammonium, benzyltrimethylammonium, benzyltriethylammonium, diallyldimethylammonium, diethylaminoethyl methacrylate, dimethylaminoethyl methacrylate, methacryloyloxyethyltrimethylammonium, 3-(methacrylamido) propyltrimethylammonium, triethylenetetramine, tetramethylguanidine, hexylamine and mixtures thereof. Specific ammonium salts include tetraethyl ammonium nitrate, tetrabutylammonium fluoride, tetraethylammonium nitrate, tetraethylammonium fluoride, benzyltributylammonium chloride, benzyltrimethylammonium chloride, benzyltriethylammonium chloride, diallyldimethylammonium chloride, diallyldiethylammonium chloride, diethylaminoethyl methacrylate, dimethylaminoethyl methacrylate, methacryloyloxyethyltrimethylammonium sulfate, methacryloyloxyethyltrimethylammonium chloride, 3-(methacrylamido) propyltrimethylammonium chloride, triethylenetetramine, tetramethylguanidine, hexylamine and mixtures comprising at least one of the foregoing. The preferred ammonium salts are tetraethyl ammonium salts, tetrabutylammonium salts, benzyltributylammonium salts, benzyltrimethylammonium salts, benzyltriethylammonium salts and mixtures thereof.

The ammonium salts are present in an amount of 1 ppm to 4 weight percent Preferably, the ammonium salt is present in an amount of 10 ppm to 2 weight percent. Most preferably, the ammonium salt is 25 ppm to 1 weight percent.

The solution enables the CMP apparatus to operate with a low pad pressure, for example at 7.5 to 25 kPa and, in certain cases, even below 7.5 kPa. The low CMP pad pressure improves polishing performance by reducing scratching and other undesired polish defects and decreases damage to fragile materials. For example, low dielectric constant materials fracture and delaminate, if exposed to high compressive forces. Further, the high barrier metal removal rate obtained by the acidic polishing solution enables effective barrier metal polishing using a low abrasive concentration and a small particle size.

For purposes of this specification, useful for preferentially removing barrier materials in the presence of nonferrous interconnect metals refers to removing the barrier material at a rate, as expressed in Angstroms per minute, of greater than the removal rate of the interconnect metal. Typically, the polishing solution has a tantalum nitride to copper selectivity of at least 1.5 to 1 as measured with a polishing pad pressure measured normal to a wafer less than 15 kPa. Preferably, the polishing solution has a tantalum nitride to copper selectivity of at least 2 to 1 as measured with a polishing pad pressure measured normal to a wafer less than 15 kPa. Most preferably, the polishing solution has a tantalum nitride to copper selectivity of at least 3 to 1. This high level of selectivity allows a chip manufacturer to remove the barrier material without removing excess dielectric or interconnect material.

For purposes of this specification, limited dielectric erosion refers to a chemical mechanical polishing process where after polishing, the dielectric has sufficient thickness to act on behalf of its intended purpose, such as being a semiconducting, masking or barrier material. In addition, the polishing solution provides a flexible tantalum nitride to dielectric selectivity. For example, the polishing solution has a tantalum nitride to TEOS selectivity of 1 to 2 to as high as 10 to 1 as measured with a polishing pad pressure measured normal to a wafer less than 15 kPa.

### EXAMPLE 1

This example shows the surface contamination of Coral carbon-doped oxide (CDO) wafers polished on a Mirra polisher at 1.5 psi (10.3 kPa) down-force, 93 rpm table speed, and 87 rpm carrier speed. Each polishing slurry had the following composition, by weight: 0.6% BTA, 4% silica abrasive particles, 0.6% H₂O₂, 0.085% TBAH, at a pH of 2.6 obtained with a balance deionized water and HNO₃ as a titrant.

TABLE 1
Surface Coverage (10¹⁰ atoms/cm²)

| | Low-Purity Silica (25 nm) | | | High-Purity Silica A* | | | High-Purity Silica B** | | |
|---|---|---|---|---|---|---|---|---|---|
| Ions: | Center | 50 mm | 90 mm | Center | 50 mm | 90 mm | Center | 50 mm | 90 mm |
| Na | 0.20 | 0.14 | 0.67 | 0.18 | 0.20 | 0.17 | 0.14 | 0.18 | 0.18 |
| Al | 3.59 | 3.58 | 2.93 | 0.20 | 0.19 | 0.20 | 0.24 | 0.13 | 0.27 |
| K | 1.42 | 0.97 | 1.61 | 0.12 | 0.12 | 0.09 | 0.13 | 0.11 | 0.11 |
| Cu | 5.67 | 6.85 | 5.60 | nd | Nd | nd | nd | nd | nd |

nd = not determined
*Fuso (PL-3) 35 nm primary particle size and 70 nm secondary particle size.
**Fuso (PL-2) 23 nm primary particle size and 50 nm secondary particle size.

The high-purity particles provide an extremely low surface contamination of wafers when slurries with these particles are used for CMP of the wafers. In particular, the high-purity particles have specifications that include 0.30 ppm Na max., 0.20 ppm K max., 0.20 ppm Al max., and 0.10 ppm Cu max. The slurry made with high-purity silica A particles showed no detectable Al, Cu, and K but did show 0.73 ppm Na. The slurry made with high-purity silica B particles also showed no detectable Al, Cu, and K. It did show 0.60 Na. The slurry made with low-purity particles showed no detectable Cu. Al was 13.0 ppm, K was 123.0 ppm, and Na was 2.5 ppm.

### EXAMPLE 2

This example shows the contamination of Coral CDO wafers integrated through the first 150 nm of thickness. The slurries and conditions were the same as in Example 1 where CDO wafers were polished with a slurry containing either low-purity particles or high-purity silica B particles.

TABLE 2

| | Sampling Position | Na | K |
|---|---|---|---|
| Particles | (from wafer center) | (atoms/cm3) | (atoms/cm3) |
| Low-Purity Silica | 0 mm | 6.1E+15 | 5.0E+17 |
| (25 nm) | | | |
| Low-Purity Silica | 50 mm | 1.1E+16 | 6.4+17 |
| (25 nm) | | | |
| Low-Purity Silica | 90 mm | 1.1E+16 | 8.6E+17 |
| (25 nm) | | | |
| High-Purity Silica B* | 0 mm | 6.7E+14 | 2.2E+15 |
| High-Purity Silica B* | 50 mm | 1.1E+15 | 2.5E+15 |

*Fuso (PL-2) 23 nm primary particle size and 50 nm secondary particle size.

It is very difficult to strip the surface layer of a CDO. Consequently it is an advantage to have low surface contamination. The high-purity silica B particles gave a much lower surface contamination of sodium and potassium by a measurement of atoms/cm³ in the wafer surface. High-purity silica B showed at least a four fold improvement over low-purity silica in surface contamination.

### EXAMPLE 3

Removal rate of barrier (TaN) was determined with two different pads, IC1010™ and Vision Pad™ 1010 polishing pads available from Rohm and Haas Electronic Materials CMP Technologies, Newark, Del. The slurries used were as in Example 1.

TABLE 3
TaN Removal Rate

Pad

| | IC1010 | VP1010 |
|---|---|---|
| Low-Purity Silica (25 nm) | 1394 | 1198 |
| High-Purity Silica B** | 938 | 1093 |
| High-Purity Silica A* | 867 | 811 |

*Fuso (PL-3) 35 nm primary particle size and 70 nm secondary particle size.
**Fuso (PL-2) 23 nm primary particle size and 50 nm secondary particle size.

These data show that high-purity barrier slurries provide rapid removal of barrier material under standard operating conditions. The remaining insulator will be contaminant free.

1. A polishing solution useful for preferentially removing barrier materials in the presence of nonferrous interconnect metals with limited erosion of dielectrics comprising: 0 to 20 weight percent oxidizer, inhibitor for reducing removal rate of the nonferrous interconnect metals, 0.1 to 50 weight percent silica containing 0.001 to 1 ppm sodium and 0.001 to 1 ppm potassium, and balance water; and the solution having a pH of less than 3 with an inorganic acid used as the titrant.

2. The polishing solution of claim 1 including 0.001 to 3 weight percent organic-containing ammonium salt formed with 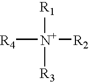
wherein R₁, R₂, R₃ and R⁴ are radicals and R₁ has a carbon chain length of 2 to 15 carbon atoms.

3. The polishing solution of claim 2 wherein the ammonium salt is formed with a compound comprising at least one of tetraethyl ammonium, tetrabutylammonium, benzyltributylammonium, benzyltrimethylammonium, benzyltriethylammonium, diallyldimethylammonium, diethylaminoethyl methacrylate, dimethylaminoethyl methacrylate, methacryloyloxyethyltrimethylammonium, 3-(methacrylamido) propyltrimethylammonium, triethylenetetramine, tetramethylguanidine, hexylamine and mixtures thereof.

4. The polishing solution of claim 1 wherein the solution contains nitric acid as the titrant and the pH level of the polishing solution is 1.5 to 2.9.

5. A polishing solution useful for preferentially removing barrier materials in the presence of nonferrous interconnect metals with limited erosion of dielectrics comprising 0.01 to 15 weight percent oxidizer, 0.001 to 10 weight percent inhibitor for reducing removal rate of the nonferrous interconnect metals, 0.001 to 3 weight percent ammonium salt, 0.1 to 40 weight percent silica containing 0.001 to 0.5 ppm sodium and −0.001 to 0.5 ppm potassium, and balance water; and the solution having a pH of less than or equal to 3.

6. The polishing solution of claim 5 including 0.001 to 2 weight percent organic-containing ammonium salt formed with 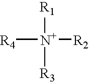
wherein R₁, R₂, R₃ and R₄ are radicals, R₁ has a carbon chain length of 2 to 15 carbon atoms.

7. The polishing solution of claim 6 wherein the ammonium salt is formed with a compound comprising at least one of tetraethyl ammonium, tetrabutylammonium, benzyltributylammonium, benzyltrimethylammonium, benzyltriethylammonium, diallyldimethylammonium, diethylaminoethyl methacrylate, dimethylaminoethyl methacrylate, methacryloyloxyethyltrimethylammonium, 3-(methacrylamido) propyltrimethylammonium, triethylenetetramine, tetramethylguanidine, hexylamine and mixtures thereof.

8. The polishing solution of claim 5 wherein the solution contains nitric acid and the pH level of the polishing solution is 1.5 to 4.

9. A method of polishing semiconductor substrates, including the steps of: polishing the semiconductor substrate with a polishing solution and a polishing pad, the polishing solution useful for preferentially removing barrier materials in the presence of nonferrous interconnect metals with limited erosion of dielectrics comprising: 0 to 20 weight percent oxidizer, inhibitor for reducing removal rate of the nonferrous interconnect metals, ammonium salt, 0.1 to 50 weight percent silica containing 0.001 to 1 ppm sodium and 0.001 to 1 ppm potassium and balance water; and the solution having a pH of less than 3 with an inorganic acid used as a titrant.
